(19) United States
(12) Patent Application Publication
(10) Pub. No.: US 2018/0026065 A1
(43) Pub. Date: Jan. 25, 2018

(54) IMAGE-SENSOR STRUCTURES

(71) Applicant: VisEra Technologies Company Limited, Hsin-Chu City (TW)

(72) Inventors: Chin-Chuan HSIEH, Hsin-Chu City (TW); Wei-Ko WANG, Taoyuan City (TW)

(21) Appl. No.: 15/215,995

(22) Filed: Jul. 21, 2016

(51) Int. Cl. H01L 27/146

(52) U.S. Cl. CPC H01L 27/14627; H01L 27/14643; H01L 27/14621

(57) ABSTRACT

An image-sensor structure is provided. The image-sensor structure includes a plurality of color filter patterns divided into a first unit including one green filter, a second unit including one green filter, a third unit including one blue filter, and a fourth unit including one red filter, wherein the first unit is adjacent to the second unit; and a plurality of microlenses formed above the color filter patterns, wherein the microlenses are divided into a first microlens unit having one microlens above the one green filter of the first unit and the one green filter of the second unit, a second microlens unit above the one blue filter of the third unit, and a third microlens unit above the one red filter of the fourth unit.

### BACKGROUND OF THE INVENTION

### Field of the Invention

The invention relates to an image-sensor structure, and more particularly to an image-sensor structure with shared microlenses.

### Description of the Related Art

An image sensor is a kind of semiconductor device that transforms photons into electrical signals. Image sensors can be generally classified into charge coupled devices (CCDs) and complementary metal oxide semiconductor (CMOS) image sensors. Among these image sensors, a CMOS image sensor comprises a photodiode for detecting incident light and transforming it into electrical signals, and logic circuits for transmitting and processing the electrical signals.

Recently, phase detection autofocus (PDAF) technology has been introduced into DSLR, DSC and Smart Phone Cameras. The principle is to have a pair of half opaque green pixels with a whole microlens thereabove. The differential signals of both green pixels create the phase detection autofocus function. However, these two pixels lose half of the incoming light, less than standard green pixels, resulting in poor signal capture.

Therefore, development of a novel image-sensor structure which is capable of performing a phase detection autofocus (PDAF) function and a quality image capture effect is desirable.

### BRIEF SUMMARY OF THE INVENTION

One embodiment of the invention provides an image-sensor structure comprising a plurality of color filter patterns divided into a first unit comprising one green filter, a second unit comprising one green filter, a third unit comprising one blue filter, and a fourth unit comprising one red filter, wherein the first unit is adjacent to the second unit; and a plurality of microlenses formed above the color filter patterns, wherein the microlenses are divided into a first microlens unit having one microlens above the one green filter of the first unit and the one green filter of the second unit, a second microlens unit above the one blue filter of the third unit, and a third microlens unit above the one red filter of the fourth unit.

One embodiment of the invention provides an image-sensor structure comprising a substrate; a plurality of photoelectric conversion units formed in the substrate; a plurality of color filter patterns formed above the substrate and the photoelectric conversion units, wherein the color filter patterns are divided into a first unit comprising two green filters, a second unit comprising two green filters, a third unit comprising one blue filter and one red filter, and a fourth unit comprising one blue filter and one red filter, wherein the first unit is adjacent to the second unit along a horizontal direction or along a diagonal direction; and a plurality of microlenses formed above the color filter patterns, wherein the microlenses are divided into a first microlens unit comprising one microlens covering the two green filters of the first unit, a second microlens unit comprising one microlens covering the two green filters of the second unit, a third microlens unit comprising two microlenses respectively covering the one blue filter and the one red filter of the third unit, and a fourth microlens unit comprising two microlenses respectively covering the one blue filter and the one red filter of the fourth unit.

One embodiment of the invention provides an image-sensor structure comprising a substrate; a plurality of photoelectric conversion units formed in the substrate; a plurality of color filter patterns formed above the substrate and the photoelectric conversion units, wherein the color filter patterns are divided into a first unit comprising one green filter and a metal pattern adjacent to the one green filter, a second unit comprising one green filter and a metal pattern adjacent to the one green filter, a third unit comprising one blue filter or one red filter, and a fourth unit comprising one blue filter or one red filter, wherein the first unit is adjacent to the second unit along a horizontal direction; and a plurality of microlenses formed above the color filter patterns, wherein the microlenses are divided into a first microlens unit comprising one microlens covering the one green filter of the first unit and the one green filter of the second unit, a second microlens unit comprising one microlens covering the one blue filter or the one red filter of the third unit, and a third microlens unit comprising one microlens covering the one blue filter or the one red filter of the fourth unit.

The invention provides a non-traditional microlens covering two adjacent green pixels or photodiodes. The two green pixels provide a green light signal by the sum of these two pixels. The two green pixels provide phase differential auto-focus signals.

The specific non-traditional microlens shape creates the maximal intensity located at the interface between the two green pixels and the maximal signal by the sum of the two green pixels. Optionally, the radius of curvature of the non-traditional microlens shape is partially identical to a standard microlens. Also, a microlens covering a pair of adjacent half opaque green pixels is suitable. Additionally, a non-traditional microlens covers two standard microlenses above the two green pixels or photodiodes, and the two standard microlenses have a refractive index larger than that of the non-traditional microlens.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a cross-sectional view of an image-sensor structure in accordance with one embodiment of the invention;

FIG. 2A is a top view of an arrangement of color filter patterns and a profile of microlenses of a pixel unit of an image-sensor structure in accordance with one embodiment of the invention;

FIG. 2B is a top view of an array constituted by the repeating of the pixel unit of FIG. 2A in accordance with one embodiment of the invention;

FIG. 3A is a top view of an arrangement of color filter patterns and a profile of microlenses of a pixel unit of an image-sensor structure in accordance with one embodiment of the invention;

FIG. 3B is a top view of an array constituted by the repeating of the pixel unit of FIG. 3A in accordance with one embodiment of the invention;

FIG. 4 is a cross-sectional view of an image-sensor structure in accordance with one embodiment of the invention;

FIG. 5 is a cross-sectional view of an image-sensor structure in accordance with one embodiment of the invention;

FIG. 6 is a cross-sectional view of an image-sensor structure in accordance with one embodiment of the invention;

FIG. 7 is a cross-sectional view of an image-sensor structure in accordance with one embodiment of the invention;

FIG. 8A is a top view of an arrangement of color filter patterns and a profile of microlenses of a pixel unit of an image-sensor structure in accordance with one embodiment of the invention; and

FIG. 8B is a top view of an array constituted by the repeating of the pixel unit of FIG. 8A in accordance with one embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

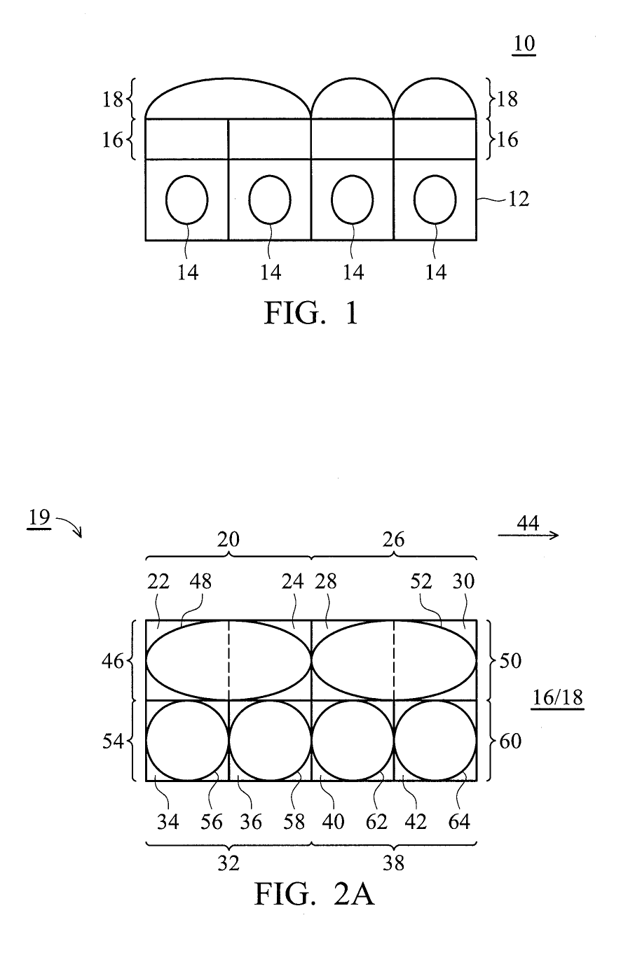

Referring to FIG. 1, in accordance with one embodiment of the invention, an image-sensor structure 10 is provided. FIG. 1 is a cross-sectional view of the image-sensor structure 10.

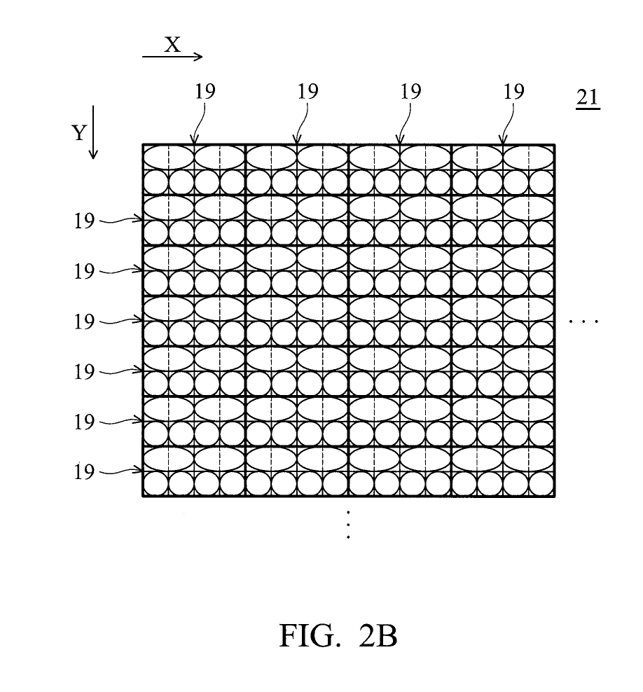

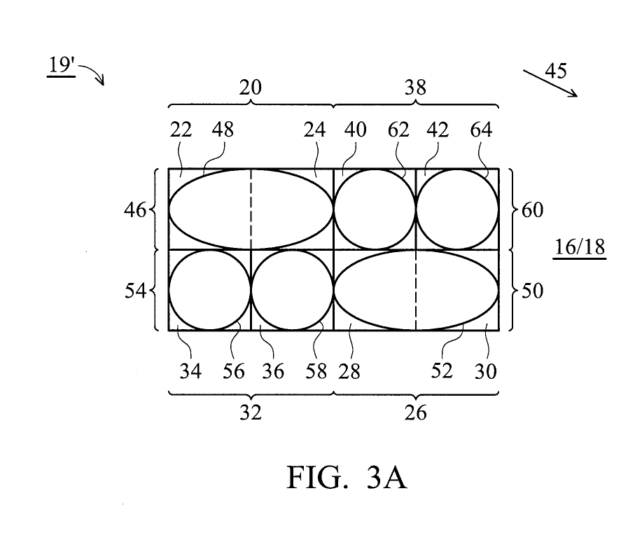

The image-sensor structure 10 comprises a substrate 12, a plurality of photoelectric conversion units 14 formed in the substrate 12, a plurality of color filter patterns 16 formed above the substrate 12 and the photoelectric conversion units 14, and a plurality of microlenses 18 formed above the color filter patterns 16. In some embodiments, top views of various arrangements of the color filter patterns 16 and profiles of the microlenses 18 of various pixel units 19 and 19′ of the image-sensor structure 10 are disclosed in FIGS. 2A and 3A.

In one embodiment, referring to FIG. 2A, in the pixel unit 19, the color filter patterns 16 are divided into a first color filter pattern unit 20 comprising two green filter patterns 22 and 24, a second color filter pattern unit 26 comprising two green filter patterns 28 and 30, a third color filter pattern unit 32 comprising one blue filter pattern 34 and one red filter pattern 36, and a fourth color filter pattern unit 38 comprising one blue filter pattern 40 and one red filter pattern 42. In FIG. 2A, the first color filter pattern unit 20 is adjacent to the second color filter pattern unit 26 along a horizontal direction 44.

Additionally, the microlenses 18 are divided into a first microlens unit 46 comprising one microlens 48 covering the two green filter patterns 22 and 24 of the first color filter pattern unit 20, a second microlens unit 50 comprising one microlens 52 covering the two green filter patterns 28 and 30 of the second color filter pattern unit 26, a third microlens unit 54 comprising two microlenses 56 and 58 respectively covering the one blue filter pattern 34 and the one red filter pattern 36 of the third color filter pattern unit 32, and a fourth microlens unit 60 comprising two microlenses 62 and 64 respectively covering the one blue filter pattern 40 and the one red filter pattern 42 of the fourth color filter pattern unit 38.

Referring to FIG. 2B, FIG. 2B is a top view of an array 21 constituted by the repeating of the pixel unit 19 of FIG. 2A. The pixel unit 19 is repeatedly arranged and extended along x direction and y direction to form the array 21.

In one embodiment, referring to FIG. 3A, in the pixel unit 19′, the color filter patterns 16 are divided into a first color filter pattern unit 20 comprising two green filter patterns 22 and 24, a second color filter pattern unit 26 comprising two green filter patterns 28 and 30, a third color filter pattern unit 32 comprising one blue filter pattern 34 and one red filter pattern 36, and a fourth color filter pattern unit 38 comprising one blue filter pattern 40 and one red filter pattern 42. In FIG. 3A, the first color filter pattern unit 20 is adjacent to the second color filter pattern unit 26 along a diagonal direction 45.

Additionally, the microlenses 18 are divided into a first microlens unit 46 comprising one microlens 48 covering the two green filter patterns 22 and 24 of the first color filter pattern unit 20, a second microlens unit 50 comprising one microlens 52 covering the two green filter patterns 28 and 30 of the second color filter pattern unit 26, a third microlens unit 54 comprising two microlenses 56 and 58 respectively covering the one blue filter pattern 34 and the one red filter pattern 36 of the third color filter pattern unit 32, and a fourth microlens unit 60 comprising two microlenses 62 and 64 respectively covering the one blue filter pattern 40 and the one red filter pattern 42 of the fourth color filter pattern unit 38.

Referring to FIG. 3B, FIG. 3B is a top view of an array 21′ constituted by the repeating of the pixel unit 19′ of FIG. 3A. The pixel unit 19′ is repeatedly arranged and extended along x direction and y direction to form the array 21′.

In some embodiments, the photoelectric conversion unit 14 comprises a photodiode.

In some embodiments, the two green filter patterns 22 and 24 are adjacent with each other along the horizontal direction 44 in the first color filter pattern unit 20.

In some embodiments, the two green filter patterns 28 and 30 are adjacent with each other along the horizontal direction 44 in the second color filter pattern unit 26.

In some embodiments, the one blue filter pattern 34 and the one red filter pattern 36 are adjacent with each other along the horizontal direction 44 in the third color filter pattern unit 32.

In some embodiments, the one blue filter pattern 40 and the one red filter pattern 42 are adjacent with each other along the horizontal direction 44 in the fourth color filter pattern unit 38.

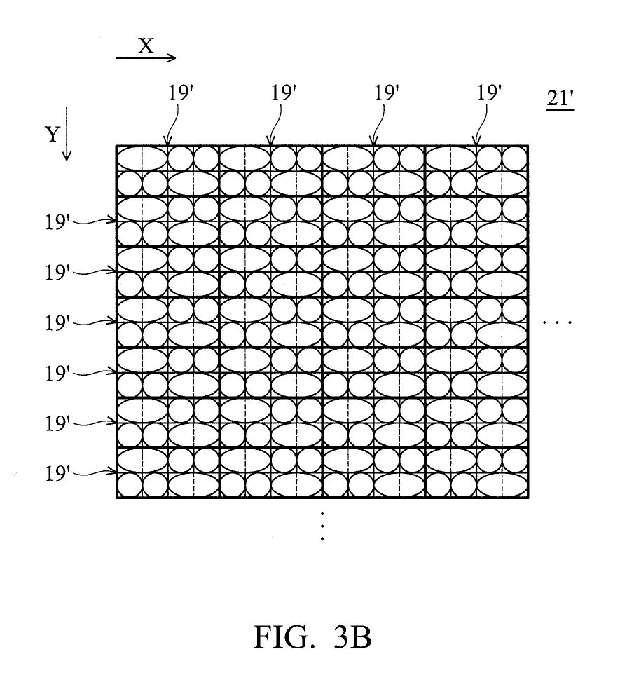

Various profiles and combinations of the microlenses 18 are shown in FIGS. 4-6. FIGS. 4-6 are cross-sectional views of a part of the image-sensor structure 10.

In FIG. 4, the first color filter pattern unit 20 comprises two green filter patterns 22 and 24. The third color filter pattern unit 32 comprises one blue filter pattern 34 and one red filter pattern 36. The first microlens unit 46 comprises one microlens 48 covering the two green filter patterns 22 and 24 of the first color filter pattern unit 20. The third microlens unit 54 comprises two microlenses 56 and 58 respectively covering the one blue filter pattern 34 and the one red filter pattern 36 of the third color filter pattern unit 32. Specifically, the one microlens 48 of the first microlens unit 46 has a height H which is the same as the height H′ of the microlenses 56 and 58 of the third microlens unit 54.

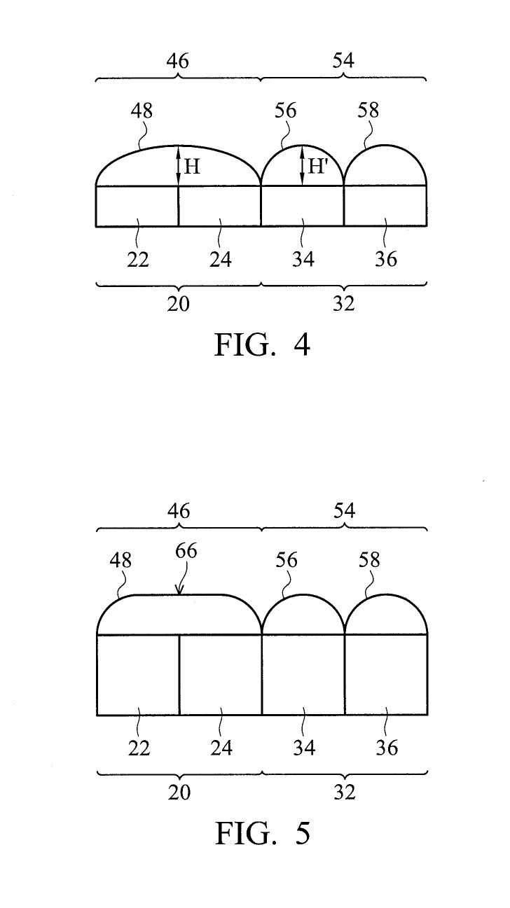

In FIG. 5, the first color filter pattern unit 20 comprises two green filter patterns 22 and 24. The third color filter pattern unit 32 comprises one blue filter pattern 34 and one red filter pattern 36. The first microlens unit 46 comprises one microlens 48 covering the two green filter patterns 22 and 24 of the first color filter pattern unit 20. The third microlens unit 54 comprises two microlenses 56 and 58 respectively covering the one blue filter pattern 34 and the one red filter pattern 36 of the third color filter pattern unit 32. Specifically, the one microlens 48 of the first microlens unit 46 comprises a flat upper surface 66.

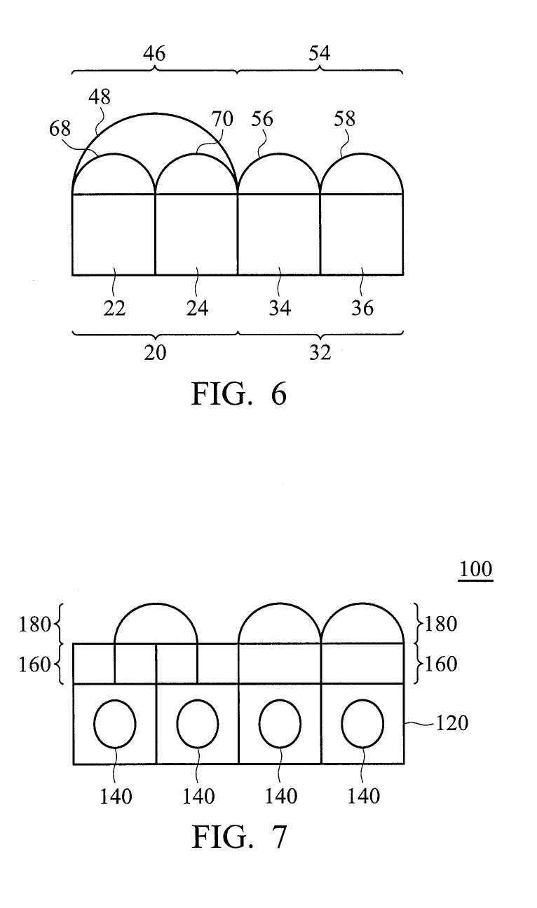

In FIG. 6, the first color filter pattern unit 20 comprises two green filter patterns 22 and 24. The third color filter pattern unit 32 comprises one blue filter pattern 34 and one red filter pattern 36. The first microlens unit 46 comprises one microlens 48 covering the two green filter patterns 22 and 24 of the first color filter pattern unit 20. The third microlens unit 54 comprises two microlenses 56 and 58 respectively covering the one blue filter pattern 34 and the one red filter pattern 36 of the third color filter pattern unit 32. Specifically, the first microlens unit 46 further comprises two sub-microlenses 68 and 70 formed inside the one microlens 48 of the first microlens unit 46. The two sub-microlenses 68 and 70 respectively covering the two green filter patterns 22 and 24 of the first color filter pattern unit 20.

In some embodiments, the two sub-microlenses 68 and 70 have a refractive index larger than the refractive index of the one microlens 48 of the first microlens unit 46.

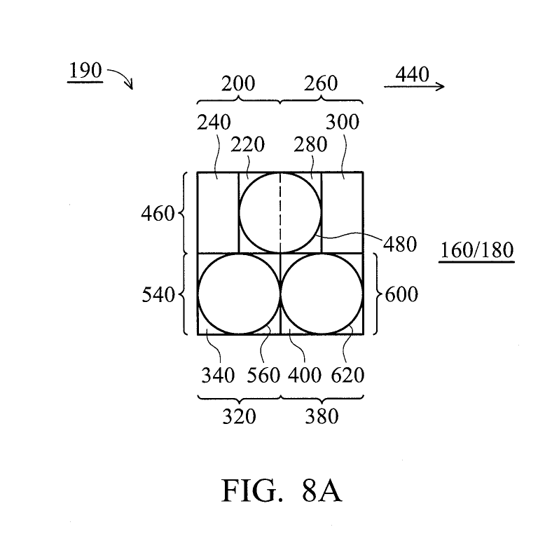

Referring to FIG. 7, in accordance with one embodiment of the invention, an image-sensor structure 100 is provided. FIG. 7 is a cross-sectional view of the image-sensor structure 100.

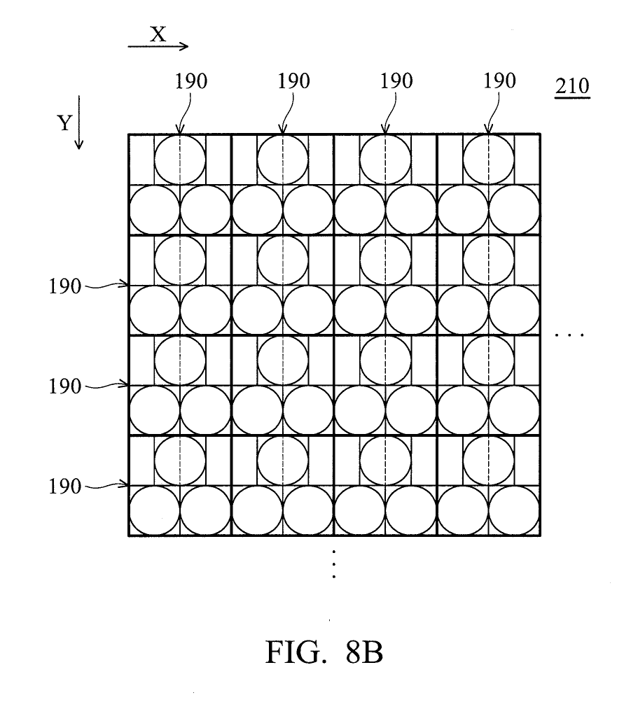

The image-sensor structure 100 comprises a substrate 120, a plurality of photoelectric conversion units 140 formed in the substrate 120, a plurality of color filter patterns 160 formed above the substrate 120 and the photoelectric conversion units 140, and a plurality of microlenses 180 formed above the color filter patterns 160. In some embodiments, a top view of the arrangement of the color filter patterns 160 and the profile of the microlenses 180 of a pixel unit 190 of the image-sensor structure 100 is disclosed in FIG. 8A.

Referring to FIG. 8A, in the pixel unit 190, the color filter patterns 160 are divided into a first color filter pattern unit 200 comprising one green filter pattern 220 and a metal pattern 240 adjacent to the one green filter pattern 220, a second color filter pattern unit 260 comprising one green filter pattern 280 and a metal pattern 300 adjacent to the one green filter pattern 280, a third color filter pattern unit 320 comprising one blue filter pattern 340 or one red filter pattern 340, and a fourth color filter pattern unit 380 comprising one blue filter pattern 400 or one red filter pattern 400. The first color filter pattern unit 200 is adjacent to the second color filter pattern unit 260 along a horizontal direction 440.

Additionally, the microlenses 180 are divided into a first microlens unit 460 comprising one microlens 480 covering the one green filter pattern 220 of the first color filter pattern unit 200 and the one green filter pattern 280 of the second color filter pattern unit 260, a second microlens unit 540 comprising one microlens 560 covering the one blue filter pattern 340 or the one red filter pattern 340 of the third color filter pattern unit 320, and a third microlens unit 600 comprising one microlens 620 covering the one blue filter pattern 400 or the one red filter pattern 400 of the fourth color filter pattern unit 380.

Referring to FIG. 8B, FIG. 8B is a top view of an array 210 constituted by the repeating of the pixel unit 190 of FIG. 8A. The pixel unit 190 is repeatedly arranged and extended along x direction and y direction to form the array 210.

The invention provides a non-traditional microlens covering two adjacent green pixels or photodiodes. The two green pixels provide a green light signal by the sum of these two pixels. The two green pixels provide phase differential auto-focus signals.

The specific non-traditional microlens shape creates the maximal intensity located at the interface between the two green pixels and the maximal signal by the sum of the two green pixels. Optionally, the radius of curvature of the non-traditional microlens shape is partially identical to a standard microlens. Also, a microlens covering a pair of adjacent half opaque green pixels is suitable. Additionally, a non-traditional microlens covers two standard microlenses above the two green pixels or photodiodes, and the two standard microlenses have a refractive index larger than that of the non-traditional microlens.

While the invention has been described by way of example and in terms of preferred embodiment, it is to be understood that the invention is not limited thereto. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An image-sensor structure, comprising:
a plurality of color filter patterns divided into a first unit comprising one green filter, a second unit comprising one green filter, a third unit comprising one blue filter, and a fourth unit comprising one red filter, wherein the first unit is adjacent to the second unit; and
a plurality of microlenses formed above the color filter patterns, wherein the microlenses are divided into a first microlens unit having one microlens above the one green filter of the first unit and the one green filter of the second unit, a second microlens unit above the one blue filter of the third unit, and a third microlens unit above the one red filter of the fourth unit.

2. The image-sensor structure as claimed in claim 1, wherein the first unit is adjacent to the second unit along a horizontal direction.

3. The image-sensor structure as claimed in claim 1, wherein the first unit further comprises another green filter adjacent to the one green filter along a horizontal direction.

4. The image-sensor structure as claimed in claim 1, wherein the second unit further comprises another green filter adjacent to the one green filter along a horizontal direction.

5. The image-sensor structure as claimed in claim 1, wherein the third unit further comprises another red filter adjacent to the one blue filter along a horizontal direction.

6. The image-sensor structure as claimed in claim 1, wherein the fourth unit further comprises another blue filter adjacent to the one red filter along a horizontal direction.

7. The image-sensor structure as claimed in claim 1, wherein the first unit further comprises a metal pattern adjacent to the one green filter along a horizontal direction.

8. The image-sensor structure as claimed in claim 1, wherein the second unit further comprises a metal pattern adjacent to the one green filter along a horizontal direction.

9. The image-sensor structure as claimed in claim 1, wherein the one microlens of the first microlens unit has a height which is the same as that of the microlenses of the second microlens unit and the third microlens unit.

10. The image-sensor structure as claimed in claim 1, wherein the one microlens of the first microlens unit comprises a flat upper surface.

11. The image-sensor structure as claimed in claim 1, wherein the first microlens unit further comprises two sub-microlenses covered by the one microlens respectively above the one green filter of the first unit and the one green filter of the second unit.

12. The image-sensor structure as claimed in claim 11, wherein the two sub-microlenses have a refractive index larger than that of the one microlens of the first microlens unit.

13. An image-sensor structure, comprising:
a substrate;
a plurality of photoelectric conversion units formed in the substrate;
a plurality of color filter patterns formed above the substrate and the photoelectric conversion units, wherein the color filter patterns are divided into a first unit comprising two green filters, a second unit comprising two green filters, a third unit comprising one blue filter and one red filter, and a fourth unit comprising one blue filter and one red filter, wherein the first unit is adjacent to the second unit along a horizontal direction or along a diagonal direction; and
a plurality of microlenses formed above the color filter patterns, wherein the microlenses are divided into a first microlens unit comprising one microlens covering the two green filters of the first unit, a second microlens unit comprising one microlens covering the two green filters of the second unit, a third microlens unit comprising two microlenses respectively covering the one blue filter and the one red filter of the third unit, and a fourth microlens unit comprising two microlenses respectively covering the one blue filter and the one red filter of the fourth unit.

14. The image-sensor structure as claimed in claim 13, wherein the two green filters are adjacent with each other along the horizontal direction in the first unit, and the two green filters are adjacent with each other along the horizontal direction in the second unit.

15. The image-sensor structure as claimed in claim 13, wherein the one blue filter and the one red filter are adjacent with each other along the horizontal direction in the third unit, and the one blue filter and the one red filter are adjacent with each other along the horizontal direction in the fourth unit.

16. The image-sensor structure as claimed in claim 13, wherein the one microlens of the first microlens unit and the second microlens unit comprises a flat upper surface.

17. The image-sensor structure as claimed in claim 13, wherein the first microlens unit and the second microlens unit further comprise two sub-microlenses formed inside the one microlens thereof, the two sub-microlenses respectively covering the two green filters of the first unit and the second unit.

18. The image-sensor structure as claimed in claim 17, wherein the two sub-microlenses have a refractive index larger than that of the one microlens of the first microlens unit and the second microlens unit.

19. An image-sensor structure, comprising:
a substrate;
a plurality of photoelectric conversion units formed in the substrate;
a plurality of color filter patterns formed above the substrate and the photoelectric conversion units, wherein the color filter patterns are divided into a first unit comprising one green filter and a metal pattern adjacent to the one green filter, a second unit comprising one green filter and a metal pattern adjacent to the one green filter, a third unit comprising one blue filter or one red filter, and a fourth unit comprising one blue filter or one red filter, wherein the first unit is adjacent to the second unit along a horizontal direction; and
a plurality of microlenses formed above the color filter patterns, wherein the microlenses are divided into a first microlens unit comprising one microlens covering the one green filter of the first unit and the one green filter of the second unit, a second microlens unit comprising one microlens covering the one blue filter or the one red filter of the third unit, and a third microlens unit comprising one microlens covering the one blue filter or the one red filter of the fourth unit.

20. The image-sensor structure as claimed in claim 19, wherein the one green filter and the metal pattern are adjacent with each other along the horizontal direction in the first unit, and the one green filter and the metal pattern are adjacent with each other along the horizontal direction in the second unit.
